(19) United States
(12) Patent Application Publication
(10) Pub. No.: US 2006/0202317 A1
(43) Pub. Date: Sep. 14, 2006

(54) Method for MCP packaging for balanced performance

(76) Inventors: Farid Barakat, Raleigh, NC (US); Petros Negussu, Morrisville, NC (US); Thoai Thai Le, Cary, NC (US)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/208,362

(22) Filed: Aug. 19, 2005

Related U.S. Application Data
(60) Provisional application No. 60/661,639, filed on Mar. 14, 2005.

(51) Int. Cl. H01L 23/02

(52) U.S. Cl. 257/686

(57) ABSTRACT

Embodiments of the invention generally provide methods and apparatus for constructing multi chip packages having balance performance as between the various integrated circuits in a stack. In one embodiment, contacts on an outer surface of a first pad are “redistributed” from one area of the outer surface to another area of the first pad (e.g., to a different area of the outer surface). A second chip is adjacent to, and laterally offset with, the first chip, thereby exposing the redistributed contacts of the first chip.

### CROSS-REFERENCE TO RELATED APPLICATIONS

This application is related to U.S. patent application Ser. No. 11/039,293, Attorney Docket No. INFN/0097 (2004P53356US), entitled SIGNAL REDISTRIBUTION USING BRIDGE LAYER FOR MULTICHIP MODULE, filed Jan. 20, 2005, by Thoai Thai Le et al., and U.S. patent application Ser. No. 11/079,620, Attorney Docket No. INFN/WB0157, entitled METHOD FOR PRODUCING CHIP STACKS AND CHIP STACKS FORMED BY INTEGRATED DEVICES, filed Mar. 14, 2005, by Harald Gross. Each of the aforementioned related patent applications is herein incorporated by reference in its entirety.

### BACKGROUND OF THE INVENTION

1. Field of the Invention

The invention generally relates to multichip modules (MCMs).

2. Description of the Related Art

Many electronic applications require a set of integrated circuit (IC) chips that are packaged together, for example, on a common printed circuit (PC) board. For example, many applications call for a processor and some type of memory or different types of memory, such as volatile memory (e.g., dynamic random access memory, or DRAM) and non-volatile (e.g., flash) memory, to be included on the same PC board. If economies of scale dictate, it is sometimes more cost effective to package these integrated circuits together into a single multi-chip package (MCP; which may also be referred to as a multi-chip module, or MCM)), that allows tight integration of the devices and occupies less PC board space.

FIG. 1 illustrates a prior art MCP 100 prior to package encapsulation. MCP 100 comprises an upper integrated circuit (IC) 110 positioned over a lower integrated circuit 120 which is positioned over a package substrate 140. Pads 160 formed on the upper and lower ICs 110, 120 are connected to pins 170 on the substrate 140 with thin bond wires 150, typically made of gold or aluminum. The bond wires are connected to the ICs 110, 120 and the substrate 140 using a wire bonding technique.

FIG. 1 illustrates a particular arrangement in which the upper and lower ICs 110 and 120 are of the same type and dimensions, such as where the ICs are both dynamic random access memory (DRAM) chips. The goal in such an arrangement is to either reach a higher density with the same data bus width (i.e. 256M×16 to 512M×16) or to get a higher performance by expanding the data bus width (i.e. 256M×16 to 512M×32) and at the same time maintain an operation specification that is slightly different (operating voltage, frequency) compared to the same chip in a single die package.

However, one problem that occurs with wire bonding in MCP is that the various ICs perform differently relative to one another due to the different bond wire lengths. For example, in FIGS. 1 and 2, the bond wire connecting the upper IC 110 is relatively longer than the bond wire connecting the lower IC 120. The difference in bond wire length results in a longer time in flight for signals propagating through the bond wire connecting the upper IC 110 as compared to the signals propagating through the bond wire connecting the lower IC 120. As a result, there is a RLC value difference resulting in an inferior performance of the upper IC 110 relative to the performance of the lower IC 120. Consequently, the specification of the overall MCP performance is reduced.

Accordingly, what is needed is techniques and apparatus for improved multi-chip packaging.

### SUMMARY OF THE INVENTION

Embodiments of the invention generally provide methods and apparatus for constructing multi chip packages. The following embodiments are merely illustrative and do not exhaustively encompass the scope of the invention.

One embodiment provides a method for forming multi-chip packages in which a first integrated circuit is positioned in a face-up position over a substrate defining a first substrate surface and comprising a plurality of contact areas, wherein in the face-up position a first surface of the first integrated circuit and the first substrate surface are in facing relationship with respect to one another and a second surface of the first integrated circuit faces away from the substrate; wherein the first integrated circuit comprises a first plurality of pads disposed on the second surface of the first integrated circuit. At least a portion of a second integrated circuit is positioned over at least a portion of the first integrated circuit so that the second surface of the first integrated circuit is facing a first surface of the second integrated circuit, wherein the second integrated circuit comprises a second plurality of pads; and wherein positioning at least a portion of the second integrated circuit comprises laterally offsetting the second integrated circuit relative to the first integrated circuit to substantially prevent the first plurality of pads formed on the first integrated circuit from being covered by the second integrated circuit. The first and second plurality of pads are coupled to the plurality of contact areas with electrical conductors.

Another method for forming multi-chip packages includes providing a first integrated circuit comprising a first plurality of pads disposed on a first surface of the first integrated circuit; wherein the first plurality of pads comprises a first plurality of inner pads disposed on an inner portion of the first surface and a first plurality of outer pads disposed on the first surface of the first integrated circuit and outwardly of the first plurality of inner pads; and further comprising a plurality of redistribution lines disposed on the first surface of the first integrated circuit and connecting the first plurality of inner pads to the first plurality of outer pads. The first integrated circuit is positioned in a face-up position over a substrate defining a first substrate surface and comprising a plurality of contact areas, wherein in the face-up position a first surface of the first integrated circuit and the first substrate surface are facing in a common direction. At least a portion of a second integrated circuit is positioned over at least a portion of the first integrated circuit so that the first surface of the first integrated circuit is facing a first surface of the second integrated circuit, wherein the second integrated circuit comprises a second plurality of pads. The first plurality of pads and the second plurality of pads are coupled to the plurality of contact areas with electrical conductors, wherein coupling the first plurality of pads comprises coupling the outer plurality of pads to the electrical conductors, whereby an electrical connection is made between the first plurality of inner pads and the plurality of contact areas via the electrical conductors.

Yet another embodiment provides a multi-chip package having a substrate defining a first substrate surface and comprising a plurality of contact areas. A first integrated circuit is disposed over the substrate in a face-up position, so that a first surface of the first integrated circuit and the first substrate surface are in facing relationship with respect to one another and a second surface of the first integrated circuit faces away from the substrate; wherein the first integrated circuit comprises a first plurality of pads disposed on the second surface of the first integrated circuit. A second integrated circuit is disposed over at least a portion of the first integrated circuit so that the second surface of the first integrated circuit is facing a first surface of the second integrated circuit, wherein the second integrated circuit comprises a second plurality of pads; and wherein the second integrated circuit is laterally offset relative to the first integrated circuit to substantially prevent the first plurality of pads formed on the first integrated circuit from being covered by the second integrated circuit. Electrical conductors couple the first and second plurality of pads to the plurality of contact areas.

Yet another embodiment provides a multi-chip package having a substrate defining a first substrate surface and comprising a plurality of contact areas. A first memory chip is disposed in a face-up position over the substrate so that a first surface of the first memory chip and the first substrate surface are in facing relationship with respect to one another and a second surface of the first memory chip faces away from the substrate; wherein the first memory chip comprises a first plurality of pads disposed on one of the first surface and the second surface of the first memory chip. A second memory chip disposed over at least a portion of the first integrated circuit so that the second surface of the first memory chip is facing a first surface of the second memory chip, wherein the second memory chip comprises a second plurality of pads; and wherein the second memory chip is laterally offset relative to the first memory chip so that the second memory chip forms an overhang relative to the first memory chip. Bond wires couple the first and second plurality of pads to the plurality of contact areas.

Still another embodiment provides a multi-chip package having a substrate defining a first substrate surface and comprising a plurality of contact areas. A first memory chip is in a face-up position over the substrate so that a first surface of the first memory chip and the first substrate surface are in facing relationship with respect to one another and a second surface of the first memory chip faces away from the substrate; wherein the first memory chip comprises a redistribution layer comprising a plurality of inner contacts coupled to a plurality of outer pads via respective traces; the inner pads being located in an inner region of the second surface and the outer pads being located being located in an outer region of the second surface; a second memory chip having the same dimensions as the first memory chip and disposed over at least a portion of the first integrated circuit so that the second surface of the first memory chip is facing a first surface of the second memory chip, wherein the second memory chip comprises a plurality of pads; and wherein the second memory chip is sufficiently laterally offset relative to the first memory chip to expose the outer region and substantially prevent the plurality of outer pads from being covered by the second memory chip. Bond wires couple the outer pads of the first memory chip and the plurality of pads of the second memory chip to the plurality of contact areas.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a side view of a prior art multi-chip package prior to package encapsulation.

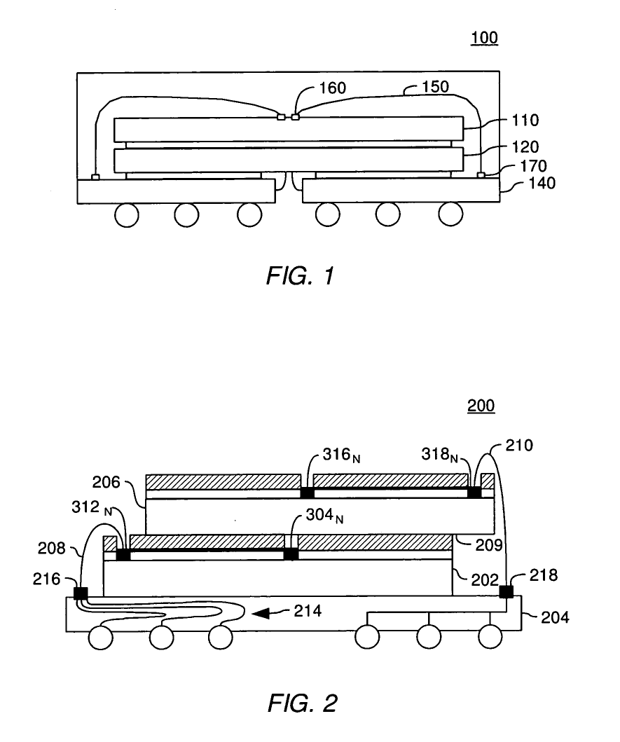

FIG. 2 is a side view of a multi-chip package prior to package encapsulation, according to one embodiment of the present invention.

FIG. 3 is a perspective view of a first die having a redistribution layer disposed thereon.

FIG. 4 is a perspective view of a second die having a redistribution layer disposed thereon.

FIG. 5 is a side view of a multi-chip package prior to package encapsulation, according to one embodiment of the present invention.

### DETAILED DESCRIPTION OF THE PREFERRED EMBODIMENT

Embodiments of the invention generally provide balanced packaging methods and balanced packages. In one embodiment, the invention offers an alternative packaging method that reduces, or eliminates, the RLC difference between two or more dies in a MCP. In addition, the capacitive loading would be relatively more balanced between the dies; that is, one of the dies will not have a much greater capacitive load than another die in the package.

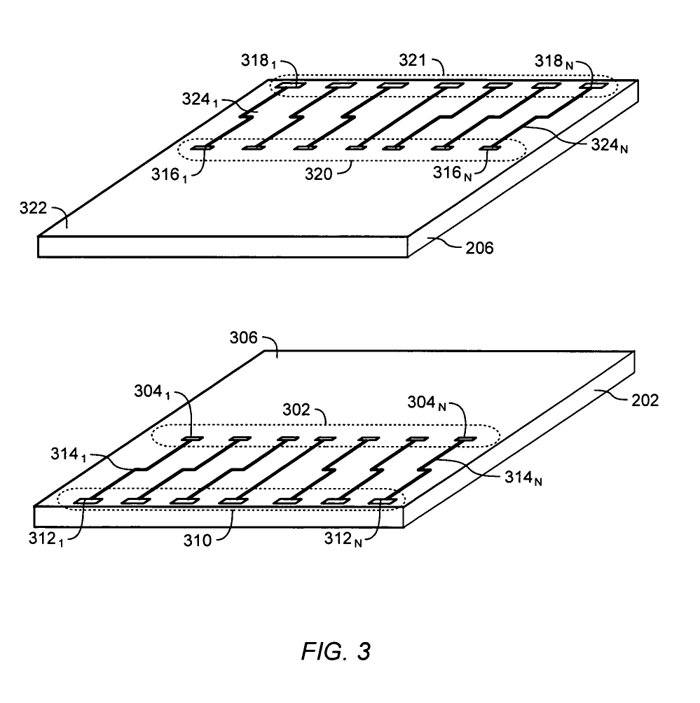

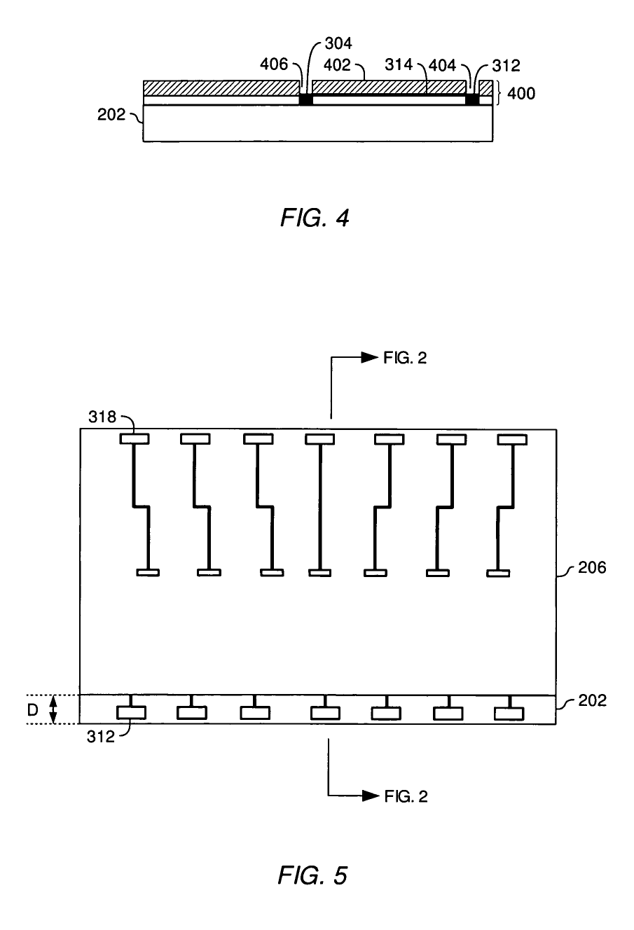

In a first embodiment, a MCP includes face-up dies, i.e., the pads on the dies face away from a substrate. FIG. 2 shows an MCP 200 with such an arrangement. Specifically, a bottom die 202 is disposed over a substrate 204 and is in a face-up orientation, meaning contact pads (316, 318) formed on an upper surface of the bottom die 202 are facing away from the substrate 204. A top die 206 is disposed over the bottom die 202 and is also in a face-up position meaning contact pads (304, 312) formed on an upper surface of the top die 206 are facing away from the substrate 204. The location of the contact pads of the bottom and top dies is illustrated in FIG. 3.

FIG. 3 shows a perspective, exploded view of the bottom die 202 and top die 206, according to one embodiment of the invention. A pattern 302 of inner pads 304₁ . . . . 304_{N} (collectively, inner pads 304) is disposed on an upper surface 306 of the bottom die 202. Illustratively, the pattern 302 is generally linear in an x-direction, however, any pattern is contemplated. Further, in the illustrative embodiment, the inner pads 304 are generally equidistant from the edges extending parallel to a longitudinal axis L (the major axis) of the die 202. As such, the interior pads 304 are in a central, inner portion of the die 202.

Illustratively, the inner pads 304 are “relocated” from the central, inner portion of the die 204 to a perimeter portion of the die 204 by the provision of outer pads 312₁ . . . 312_{N} (collectively, outer pads 312) that are coupled to the inner pads 304. The outer pads 312₁ . . . 312_{N} are arranged in a pattern 310 on the upper surface 306 at the perimeter of the die 202. The inner pads 304 and the outer pads 312₁ . . . 312_{N} are coupled to one another by a plurality of conducting members (traces) 314₁ . . . 314_{N} (collectively, conducting members 314). Each of the conducting members 314 couples an inner pad 304 to a respective outer pad 312. The conducting members 314 may be of a suitable conductive material, such as gold or copper.

The top die 206 is constructed similarly to the bottom die 202. Specifically, a pattern 320 of inner pads 316₁ . . . 316_{N} (collectively, inner pads 316) is disposed on an upper surface 322 of the top die 206. The inner pads 316 are coupled to respective outer pads 318₁ . . . 318_{N} by a plurality of conducting members (traces) 324₁₁ . . . 324_{N} (collectively, conducting members 324), the outer pads also being arranged in a pattern 321.

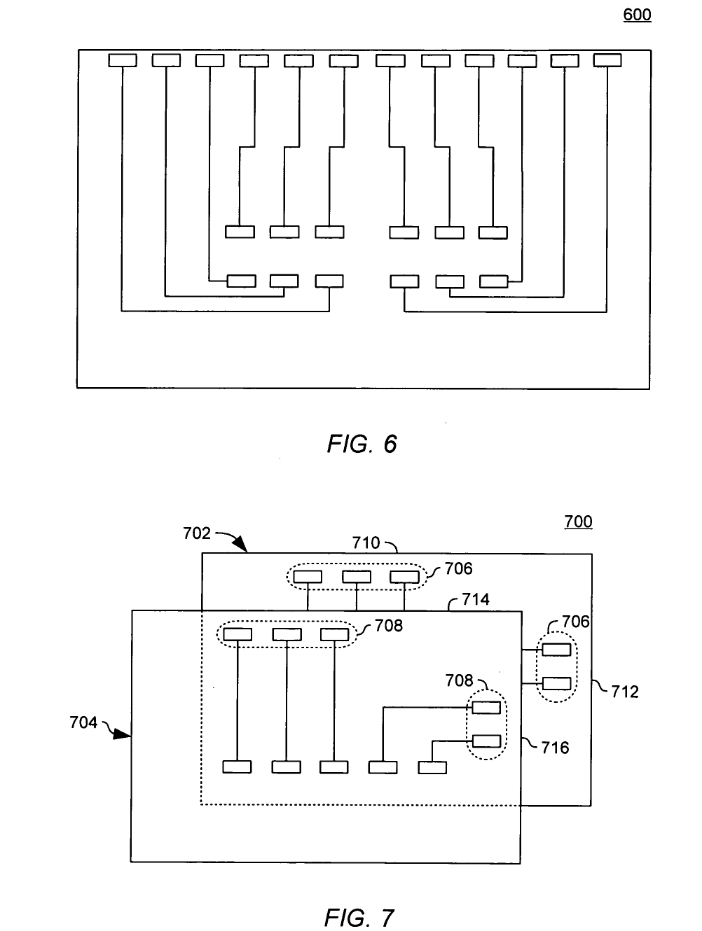

In one embodiment, the inner/outer pads and conducting members of either or both of the dies are components of a redistribution layer (RDL). One embodiment of a RDL 400 is shown in FIG. 4. Illustratively, the RDL 400 is shown disposed on the bottom die 202, but a similar RDL may be disposed on the top die 206. In the depicted embodiment, the RTL 400 includes an insulative layer 402 having the contact members 314 embedded therein. Openings 404 are formed that the respective locations of the outer pads 312 in order to expose the pads for contact to, e.g., a bond wire (shown in FIG. 2). Openings 406 may also be formed at the respective locations of the inner pads 304. The construction of redistribution layers is known to those skilled in the art and, accordingly, a detailed description is not required.

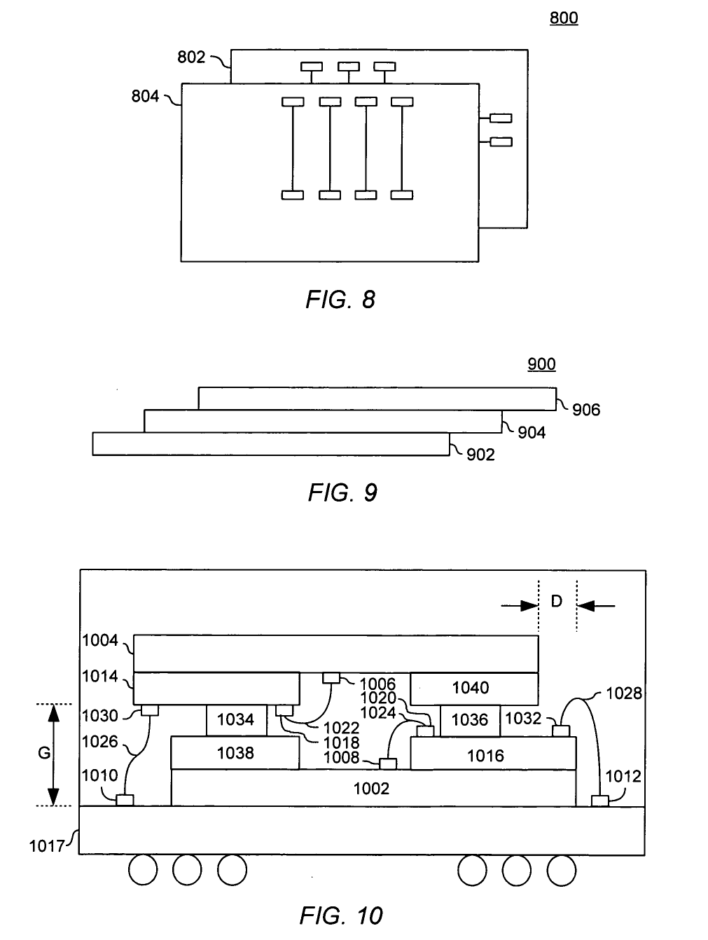

While the pad arrangements of the bottom and top dies may be the same or similar, in a given MCP (such as MCP 200, shown in FIG. 2) the orientation of the dies is such that the respective outer pads 314, 318 are on opposite sides, at least according to one embodiment of the invention. One illustration of such an orientation is shown in FIG. 5, showing a top view of the MCP 200, according to one embodiment. In addition to the relative orientation of the outer pads, the dies are laterally offset, by a distance D, so that the respective outer pads are exposed.

Referring again to FIG. 2, it can be seen that the lateral offset, D (measured as the distance between the respective central axes A1, A2 of the top and bottom dies) creates a stepped profile of the MCP 200. Depending on the relative dimensions of the dies, an overhang 209 may be produced by the top die 206. In the illustrated embodiments, the dies have the same dimensions, such as may be the case when the dies are the same type of chip (e.g., both DRAM chips). Accordingly, in order to expose the outer pads 312 of the bottom die 202 the top die 206 is laterally displaced, as shown, thereby producing the overhang 209.

Since the respective redistribution layers are on opposite sides of their respective dies, the outer contact pads 312 of the bottom die 202 remain exposed to facilitate connection of bond wires 208 (only one shown). In the illustrated embodiment, bond wires 210 (only one shown) are also connected to the contact pads 318 of the top die 206. The bond wires 208/210 are coupled to respective contacts 216/218 on the substrate 204. The resulting MCP 200 is more balanced by virtue of having bond wires with a smaller relative difference in length.

In one embodiment, the balanced performance of an MCP may be furthered by the provision of signal routing structure. For example, FIG. 2 shows a signal routing structure 214 coupled to at least one of the outer pads 312 of the bottom die 202 via a given one of the bond wires 208. The signal routing structure 214 is configured balance the performance of the bottom die with respect to the top die. For example, the signal routing structure 214 may be configured to match signal performance of signals propagating through the given one of the bond wires 208 with signals propagating through other ones of the bond wires 210 coupling the substrate 204 with the contact pads 318 of the top die 206.

The foregoing describes embodiments for redistributing (or relocating) contacts from one area of a die to another area for the purpose of achieving an advantageous stack architecture. However, it will be appreciated that the embodiments described above are merely illustrative and that other embodiments which may be contemplated are within the scope of the present invention. For example, FIG. 6 shows a top view of a die illustrating a variation on the inner pad locations and corresponding traces coupling the inner and outer pads. FIG. 7 shows an MCP 700 with an lower die 702 and a upper die 704 having a pad pattern, and corresponding stacking arrangement, in which the outer pads 706, 708 are redistributed along two orthogonally related sides 710/712, 714/716 of the respective dies. It is further contemplated that the pad patterns of the respective dies in a given stack need not be the same. For example, FIG. 8 shows one embodiment of an MCP 800 in which the outer pads of the bottom die 802 and top die 804 are arranged differently. In addition to the geometric arrangement, the number of pads may be different. It is further contemplated that a given stack may include more than two dies. For example, FIG. 9 shows a side view of a MCP 900 with three dies 902, 904, 906 having relocated outer pads and stacked according to an embodiment of the invention. Accordingly, it will be appreciated that the arrangements shown in FIGS. 2-9 is merely illustrative, and the other arrangements (symmetrical and asymmetrical) are contemplated.

Further, the facing relationship of the dies in a package may be varied according to different embodiments. In the embodiments illustrated with respect to FIGS. 2-9, the dies are facing in the same direction. However, it is also contemplated that the dies may be facing in opposite directions (i.e., away from each other) or may be facing each other. One embodiment in which adjacent dies are in a facing relationship is shown in FIG. 10. Specifically, FIG. 10 shows an embodiment of a MCP 1000 in which a bottom die 1002 is face up and a top die 1004 is face down. In illustrated embodiment, the connections between the contact pads 1006/1008 located at inner portions of the respective dies 1002/1004 and the contact areas 1010/1012 of the substrate 1017 are achieved with the provision of patterned interposer layers 1014/1016. Illustratively, connection between the inner contact pads 1006/1008 and corresponding inner contact elements 1018/1020 of the respective interposer layers 1014/1016 is made using bond wires 1022/1024. Likewise, bond wires 1026/1028 are used to connect corresponding outer contact elements 1030/1032 of the respective interposer layers to the contact areas 1010/1012 of the substrate 1017. In one embodiment, the bottom and top dies 1002/1004 may be further separated from one another with spacers 1034/1036 and fill layers 1038/1040 arranged as shown in FIG. 10. This arrangement in addition to a lateral offset, D, between the dies, creates a sufficient gap, G, allowing for the bond wires to be connected.

### CONCLUSION

Accordingly, embodiments of the invention generally provide methods and apparatus for constructing multi chip packages having balance performance as between the various integrated circuits in a stack. In one embodiment, contacts on an outer surface of a first pad are “redistributed” from one area of the outer surface to another area of the first pad (e.g., to a different area of the outer surface). A second chip is adjacent to, and laterally offset with, the first chip, thereby exposing the redistributed contacts of the first chip. The chips may be facing in the same direction, facing in opposite directions or facing one another. Further, the chips may be of the same type (e.g., both DRAMs) or different types. Likewise, the geometries may be different or the same in any given MCP. Further, although embodiments are described with respect to stacks having two dies (ICs), any number of dies is contemplated.

While the foregoing is directed to embodiments of the present invention, other and further embodiments of the invention may be devised without departing from the basic scope thereof, and the scope thereof is determined by the claims that follow.

What is claimed is:

1. A method for forming multi-chip packages, comprising:
positioning a first integrated circuit in a face-up position over a substrate defining a first substrate surface and comprising a plurality of contact areas, wherein in the face-up position a first surface of the first integrated circuit and the first substrate surface are in facing relationship with respect to one another and a second surface of the first integrated circuit faces away from the substrate; wherein the first integrated circuit comprises a first plurality of pads disposed on the second surface of the first integrated circuit;
positioning at least a portion of a second integrated circuit over at least a portion of the first integrated circuit so that the second surface of the first integrated circuit is facing a first surface of the second integrated circuit, wherein the second integrated circuit comprises a second plurality of pads; and wherein positioning at least a portion of the second integrated circuit comprises laterally offsetting the second integrated circuit relative to the first integrated circuit to substantially prevent the first plurality of pads formed on the first integrated circuit from being covered by the second integrated circuit; and
coupling the first and second plurality of pads to the plurality of contact areas with electrical conductors.

2. The method of claim 1, wherein the second plurality of pads is formed on the first surface of the second integrated circuit.

3. The method of claim 1, wherein the second plurality of pads is formed on a second surface of the second integrated circuit, the second surface being formed opposite the first surface of the second integrated circuit.

4. The method of claim 1, wherein the second plurality of pads is disposed on the first surface of the second integrated circuit, and further comprising a spacer disposed between the first integrated circuit and the second integrated circuit to form a gap therebetween.

5. The method of claim 1, wherein coupling comprises using a wire bonding technique to form the electrical conductors.

6. The method of claim 1, wherein the electrical conductors are bond wires.

7. The method of claim 1, wherein the substrate further comprises a signal routing structure coupled to at least one of the first plurality of pads via a given one of the electrical conductors; the signal routing structure being configured to match signal performance of signals propagating through the given one of the electrical conductors with signals propagating through other ones of the electrical conductors coupling the substrate with the second plurality of pads.

8. A method for forming multi-chip packages, comprising:
providing a first integrated circuit comprising a first plurality of pads disposed on a first surface of the first integrated circuit; wherein the first plurality of pads comprises a first plurality of inner pads disposed on an inner portion of the first surface and a first plurality of outer pads disposed on the first surface of the first integrated circuit and outwardly of the first plurality of inner pads; and further comprising a plurality of redistribution lines disposed on the first surface of the first integrated circuit and connecting the first plurality of inner pads to the first plurality of outer pads;
positioning the first integrated circuit in a face-up position over a substrate defining a first substrate surface and comprising a plurality of contact areas, wherein in the face-up position a first surface of the first integrated circuit and the first substrate surface are facing in a common direction;
positioning at least a portion of a second integrated circuit over at least a portion of the first integrated circuit so that the first surface of the first integrated circuit is facing a first surface of the second integrated circuit, wherein the second integrated circuit comprises a second plurality of pads; and
coupling the first plurality of pads and the second plurality of pads to the plurality of contact areas with electrical conductors, wherein coupling the first plurality of pads comprises coupling the outer plurality of pads to the electrical conductors, whereby an electrical connection is made between the first plurality of inner pads and the plurality of contact areas via the electrical conductors.

9. The method of claim 8, wherein the electrical conductors are bond wires.

10. The method of claim 8, providing a signal routing structure in the substrate, the structure being coupled to at least one of the first plurality of pads via a given one of the electrical conductors; the signal routing structure being configured to match signal performance of signals propagating through the given one of the electrical conductors with signals propagating through other ones of the electrical conductors coupling the substrate with the second plurality of pads.

11. The method of claim 8, wherein the first plurality of outer pads is disposed on a perimeter portion of the first surface of the first integrated circuit.

12. A multi-chip package, comprising:
a substrate defining a first substrate surface and comprising a plurality of contact areas;
a first integrated circuit in a face-up position over the substrate, wherein in the face-up position a first surface of the first integrated circuit and the first substrate surface are in facing relationship with respect to one another and a second surface of the first integrated circuit faces away from the substrate; wherein the first integrated circuit comprises a first plurality of pads disposed on the second surface of the first integrated circuit;
a second integrated circuit disposed over at least a portion of the first integrated circuit so that the second surface of the first integrated circuit is facing a first surface of the second integrated circuit, wherein the second integrated circuit comprises a second plurality of pads; and wherein the second integrated circuit is laterally offset relative to the first integrated circuit to substantially prevent the first plurality of pads formed on the first integrated circuit from being covered by the second integrated circuit; and
electrical conductors coupling the first and second plurality of pads to the plurality of contact areas.

13. The multi-chip package of claim 12, wherein the second plurality of pads is disposed on the first surface of the second integrated circuit, and further comprising a spacer disposed between the first integrated circuit and the second integrated circuit to form a gap therebetween.

14. The multi-chip package of claim 12, further comprising at least one other integrated circuit disposed over the second integrated circuit.

15. The multi-chip package of claim 12, wherein the first and second integrated circuits are the same type.

16. The multi-chip package of claim 12, wherein the first and second integrated circuits have the same dimensions.

17. The multi-chip package of claim 12, wherein the electrical conductors are bond wires.

18. The multi-chip package of claim 12, wherein at least one of the first plurality of pads and the second plurality of pads are part of a redistribution layer, whereby inwardly located pads are coupled to outwardly located pads with respective traces.

19. The multi-chip package of claim 12, wherein at least one of the first plurality of pads and the second plurality of pads are part of a redistribution layer, whereby inwardly located pads are coupled to outwardly located pads with respective traces, and wherein the outwardly located pads are linearly arranged on one side of the respective integrated circuit on which the redistribution layer is located.

20. A multi-chip package, comprising:
a substrate defining a first substrate surface and comprising a plurality of contact areas;
a first memory chip in a face-up position over the substrate, wherein in the face-up position a first surface of the first memory chip and the first substrate surface are in facing relationship with respect to one another and a second surface of the first memory chip faces away from the substrate; wherein the first memory chip comprises a first plurality of pads disposed on one of the first surface and the second surface of the first memory chip;
a second memory chip disposed over at least a portion of the first integrated circuit so that the second surface of the first memory chip is facing a first surface of the second memory chip, wherein the second memory chip comprises a second plurality of pads; and wherein the second memory chip is laterally offset relative to the first memory chip so that the second memory chip forms an overhang relative to the first memory chip; and
bond wires coupling the first and second plurality of pads to the plurality of contact areas.

21. The multi-chip package of claim 20, wherein the first plurality of pads are disposed on the second surface of the first memory chip.

22. The multi-chip package of claim 20, wherein the first plurality of pads is formed on an outer portion of the second surface of the first memory chip and wherein the lateral offset exposes the outer portion to substantially prevent the first plurality of pads from being covered by the second memory chip.

23. The multi-chip package of claim 20, wherein the overhang extends past an edge of the first memory chip.

24. The multi-chip package of claim 20, wherein the first and second memory chips have the same dimensions.

25. The multi-chip package of claim 20, wherein the first and second memory chips are dynamic random access memory chips.

26. The multi-chip package of claim 20, wherein at least one of the first plurality of pads and the second plurality of pads are part of a redistribution layer, whereby inwardly located pads are coupled to outwardly located pads with respective traces.

27. The multi-chip package of claim 20, further comprising a signal routing structure in the substrate, the structure being coupled to at least one of the first plurality of pads via a given one of the electrical conductors; the signal routing structure being configured to match signal performance of signals propagating through the given one of the electrical conductors with signals propagating through other ones of the electrical conductors coupling the substrate with the second plurality of pads.

28. A multi-chip package, comprising:
a substrate defining a first substrate surface and comprising a plurality of contact areas;
a first memory chip in a face-up position over the substrate, wherein in the face-up position a first surface of the first memory chip and the first substrate surface are in facing relationship with respect to one another and a second surface of the first memory chip faces away from the substrate; wherein the first memory chip comprises a redistribution layer comprising a plurality of inner contacts coupled to a plurality of outer pads via respective traces; the inner pads being located in an inner region of the second surface and the outer pads being located being located in an outer region of the second surface;
a second memory chip having the same dimensions as the first memory chip and disposed over at least a portion of the first integrated circuit so that the second surface of the first memory chip is facing a first surface of the second memory chip, wherein the second memory chip comprises a plurality of pads; and wherein the second memory chip is sufficiently laterally offset relative to the first memory chip to expose the outer region and substantially prevent the plurality of outer pads from being covered by the second memory chip; and
bond wires coupling the outer pads of the first memory chip and the plurality of pads of the second memory chip to the plurality of contact areas.

29. The multi-chip package of claim 28, further comprising a signal routing structure in the substrate, the structure being coupled to at least one of the outer pads via a given one of the electrical conductors; the signal routing structure being configured to match signal performance of signals propagating through the given one of the electrical conductors with signals propagating through other ones of the electrical conductors coupling the substrate with the plurality of pads of the second memory chip.

30. The multi-chip package of claim 28, wherein the offset causes the second memory chip to form an overhang relative to the first memory chip.

31. The multi-chip package of claim 28, wherein the outer pads are linearly arranged on one side of the first memory chip.
